(19) United States
(12) Patent Application Publication
(10) Pub. No.: US 2022/0259343 A1
(43) Pub. Date: Aug. 18, 2022

(54) POLYMERS FOR CALORIC APPLICATIONS

(71) Applicant: Iowa State University Research Foundation, Inc., Ames, IA (US)

(72) Inventors: Viktor Balema, Ames, IA (US); Vitalij Pecharsky, Ames, IA (US); Duane Johnson, Ames, IA (US)

(21) Appl. No.: 17/545,925

(22) Filed: Dec. 8, 2021

Related U.S. Application Data
(62) Division of application No. 16/755,476, filed on Apr. 10, 2020, now abandoned.
(60) Provisional application No. 62/570,741, filed on Oct. 11, 2017.

(51) Int. Cl. C08F 214/22; C08F 8/26; H01L 37/02

(52) U.S. Cl. CPC C08F 214/22; H01L 37/025; C08F 8/26

(57) ABSTRACT

Various embodiments disclosed relate to unsaturated polymers that exhibit electrocaloric properties. The polymers can be useful as heat transfer materials in heating and cooling applications.

### CROSS-REFERENCE TO RELATED APPLICATION

This application is a divisional of U.S. patent application Ser. No. 16/755,476, filed Apr. 10, 2020, which is a U.S. national stage filing under 35 U.S.C. § 371 from International Application No. PCT/US2018/055212, filed on 10 Oct. 2018, and published as WO 2019/075061 A1 on 18 Apr. 2019, which claims the benefit of priority to U.S. Provisional Patent Application Ser. No. 62/570,741, filed Oct. 11, 2017, the disclosure of which is incorporated herein in its entirety by reference.

### STATEMENT OF GOVERNMENT SUPPORT

This invention was made with Government support under contract number DE-AC02-07CH11358 awarded by the Department of Energy. The U.S. Government has certain rights in this invention.

### BACKGROUND

The electrocaloric effect (EC) describes a reversible heating or cooling of solid electrocaloric materials when they are exposed to a varying electric field (E). An electric field can change the orientation of electrically active dipoles in the material, thus altering its polarization (P) and bringing about a change in material's internal ordering, usually described as a change in its dipolar entropy S.

$${( \frac{\partial S}{\partial E} )}_{r} = {( \frac{\partial P}{\partial T} )}_{E}$$

When the electric field is changed from E₁ to E₂ under adiabatic conditions, i.e. when the heat exchange with an external environment is negligible, an electrocaloric material experiences a temperature change, ΔT_{EC}, the magnitude of which depends on the dielectric polarization (P) and the heat capacity (C_{E}) of the material in the electric field range between E₁ and E₂. ΔT_{EC} can be described as

$$Δ {T}_{EC} = - {\int }_{{ε}_{1}}^{{ε}_{2}} \frac{T ( E )}{{ε}_{e} ( T )} {( \frac{\partial P}{\partial T} )}_{E} dE$$

The electrocaloric effect (EC) offers a way to implement a highly efficient and environmentally benign refrigeration technology—solid-state caloric cooling. EC is usually observed in solids that contain electrically active dipolar constituents, such as dipoles. None of the currently known polymeric materials show the performance sufficient for their use in cooling devices. Therefore new polymer materials with improved EC are highly desirable.

### SUMMARY OF THE INVENTION

In some embodiments, the present invention provides a polymer having the formula:

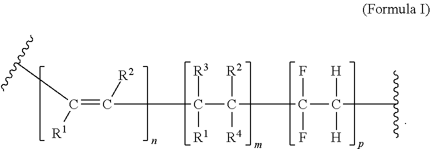

In the polymer of Formula I, n is an integer ranging from 1 to 1000, m is an integer ranging from to 1000, and p is an integer greater than n+m. At each occurrence in the polymer of Formula I, R¹, R², R³, and R⁴ are independently^{,} chosen from H, F, Cl, Br, I, —NH₂, —NHZ, —NZ₂, —BH₂, —BHZ, —BZ₂, OZ, —SeZ, —TeZ, —SO₂Z, —OCOZ, —NHCOZ, —COOZ, —CONH₂, —CONHZ, —CONZ₂, —CH₂F, and —CHF₂, wherein Z is independently at each occurrence hydrogen, alkyl, aryl, or aralkyl.

In some embodiments, the inventive polymers can advantageously be used as working bodies for cooling devices such as refrigerators, air conditioners, gas liquefiers, dehumidifiers, heat pumps, heat management devices and coatings, and in other related applications.

### BRIEF DESCRIPTION OF THE FIGURES

The drawings illustrate generally, by way of example, but not by way of limitation, various embodiments of the present invention.

FIG. 1 illustrates a DSC trace of PVDF before and after treatment with NaOH, in accordance with various embodiments.

### DETAILED DESCRIPTION OF THE INVENTION

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement. “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that the composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less. The term “substantially free of” can mean having a trivial amount of, such that a composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

The term “substituted” as used herein in conjunction with a molecule or an organic group as defined herein refers to the state in which one or more hydrogen atoms contained therein are replaced by one or more non-hydrogen atoms. The term “functional group” or “substituent” as used herein refers to a group that can be or is substituted onto a molecule or onto an organic group. Examples of substituents or functional groups include, but are not limited to, a halogen (e.g., F, Cl, Br, and I); an oxygen atom in groups such as hydroxy groups, alkoxy groups, aryloxy groups, aralkyloxy groups, oxo(carbonyl) groups, carboxyl groups including carboxylic acids, carbox:,dates, and carboxylate esters; a sulfur atom in groups such as thiol groups, alkyl and aryl sulfide groups, sulfoxide groups, sulfone groups, sulfonyl groups, and sulfonamide groups; a nitrogen atom in groups such as amines, hydroxyamines, nitriles, nitro groups, N-oxides, hydrazides, azides, and enamines; and other heteroatoms in various other groups. Non-limiting examples of substituents that can be bonded to a substituted carbon (or other) atom include F, Cl, Br, I, OR, OC(O)N(R)₂, CN, NC), NO₂, ONO₂, azido, CF₃, OCF₃, R, (C) (oxo), S (thiono), C(O), S(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, and C(═NOR)R, wherein R can be hydrogen or a carbon-based moiety; for example, R can be hydrogen, (C₁-C₁₀₀)hydrocarbyl, alkyl, aryl, or aralkyl,

The term “alkyl” as used herein refers to straight chain and branched alkyl groups and cycloalkyl groups having from 1 to 40 carbon atoms, 1 to about 20 carbon atoms, 1 to 12 carbons or, in some embodiments, from 1 to 8 carbon atoms. Examples of straight chain alkyl groups include those with from 1 to 8 carbon atoms such as methyl, ethyl, n-propyl, n-butyl, n-pentyl, n-hexyl, n-heptyl, and n-octyl groups. Examples of branched alkyl groups include, but are not limited to, isopropyl, iso-butyl, sec-butyl, t-butyl, neopentyl, isopentyl, and 2,2-dimethylpropyl groups. As used herein, the term “alkyl” encompasses n-alkyl, isoalkyl, and anteisoalkyl groups as well as other branched chain forms of alkyl. Representative substituted alkyl groups can be substituted one or more times with any of the groups listed herein, for example, amino, hydroxy, cyano, carboxy, nitro, thio, alkoxy, and halogen groups.

The term “aryl” as used herein refers to cyclic aromatic hydrocarbon groups that do not contain heteroatoms in the ring. Thus aryl groups include, but are not limited to, phenyl, azulenyl, heptalenyl, biphenyl, indacenyl, fluorenyl, phenanthrenyl, triphenylenyl, pyrenyl, naphthacenyl, chrysenyl, hiphenylenyl, anthracenyl, and naphthyl groups. In some embodiments, aryl groups contain about 6 to about N carbons in the ring portions of the groups. Aryl groups can be unsubstituted or substituted, as defined herein. Representative substituted aryl groups can be mono-substituted or substituted more than once, such as, but not limited to, a phenyl group substituted at any one or more of 2-, 3-, 4-, 5-, or 6-positions of the phenyl ring, or a naphthyl group substituted at any one or more of 2- to 8-positions thereof.

The term “aralkyl” as used herein refers to alkyl groups as defined herein in which a hydrogen or carbon bond of an alkyl group is replaced with a bond to an aryl group as defined herein. Representative aralkyl groups include benzyl and phenylethyl groups and fused (cycloalkylaryl)alkyl groups such as 4-ethyl-indanyl. Aralkenyl groups are alkenyl groups as defined herein in which a hydrogen or carbon bond of an alkyl group is replaced with a bond to an aryl group as defined herein.

The term “number-average molecular weight” (Mₙ) as used herein refers to the ordinary arithmetic mean of the molecular weight of individual molecules in a sample. It is defined as the total weight of all molecules in a sample divided by the total number of molecules in the sample. Experimentally, Mₙ is determined by analyzing a sample divided into molecular weight fractions of species i having nᵢ molecules of molecular weight Mᵢ through the formula Mₙ=ΣMᵢnᵢ/Σnᵢ. The Mₙ can be measured by a variety of well-known methods including gel permeation chromatography, spectroscopic end group analysis, and osmometry. If unspecified, molecular weights of polymers given herein are number-average molecular weights.

The term “weight-average molecular weight” as used herein refers to M_{w}, which is equal to ΣMᵢ²nᵢ/ΣMᵢnᵢ, where nᵢ is the number of molecules of molecular weight Mᵢ. In various examples, the weight-average molecular weight can be determined using light scattering, small angle neutron scattering, X-ray scattering, and sedimentation velocity.

The term “solvent” as used herein refers to a liquid that can dissolve a solid, liquid, or gas. Non-limiting examples of solvents are silicones, organic compounds, water, alcohols, ionic liquids, and supercritical fluids.

The term “independently selected from” as used herein refers to referenced groups being the same, different, or a mixture thereof, unless the context clearly indicates otherwise. Thus, under this definition, the phrase “X¹, X², and X³ are independently selected from noble gases” would include the scenario where, for example, X¹, X², and X³ are all the same, where X¹, X², and X³ are all different, where X¹ and X² are the same but X³ is different, and other analogous permutations.

As used herein, the term “polymer” refers to a molecule having at least one repeating unit and can include copolymers.

### Polymers Exhibiting an Electrocaloric Effect

In some embodiments, the present, invention provides a polymer having the formula:

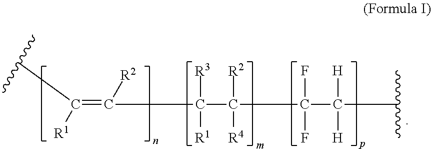

In the polymer of Formula I, n is an integer ranging from 1 to 1000, in is an integer ranging from 1 to 1000, and p is an integer greater than n+m. At each occurrence in the polymer of Formula I, R¹, R², R³, and R⁴ are independently chosen from F, Cl, Br, I, —NH₂, —NZ₂, —BZ₂, OZ, —SeZ, —TeZ, —SO₂Z, —OCOZ, —NHCOZ, —COOZ, —CONH₂, —CONHZ, —CONZ₂, —CH₂F, and —CHF₂, wherein Z is independently at each occurrence hydrogen, alkyl, aryl, or aralkyl. The polymer of Formula I can include both cis and trans orientation of substituents R1 and R2 attached to double-bonded structural segments.

The variable n can have a value of about 1 to 10000, 1 to 9000, 1 to 8000, 1 to 7000, 1 to 6000, 1 to 5000, 1 to 4000, 1 to 3000, 1 to 2000, 1 to 1000, 10 to 800, 20 to 700, 30 to 600, 40 to 500, 50 to 400, 75 to 300, or 100 to 200. The variable n can have a value of 1, 5, 10, 15, 20, 25, 30, 35, 40, 45, 50, 55, 60, 65, 70, 75, 80, 85, 90, 95, 100, 150, 200, 250, 300, 350, 400, 450, 500, 550, 600, 650, 700, 750, 800, 850, 900, 950, or 1000, or any range between these values. The variable m can have a value of about 1 to 10000, 1 to 9000, 1 to 8000, 1 to 7000, 1 to 6000, 1 to 5000, 1 to 4000, 1 to 3000, 1 to 2000, 1 to 1000, 10 to 800, 20 to 700, 30 to 600, 40 to 500, 50 to 400, 75 to 300, or 100 to 200. The variable n can have a value of 1, 5, 10, 15, :20, 25, 30, 35, 40, 45, 50, 55, 60, 65, 70, 75, 80, 85, 90, 95, 100, 150, 200, 250, 300, 350, 400, 450, 500, 550, 600, 650, 700, 750, 800, 850, 900, 950, or 1000, or any range between these values.

In some embodiments, at each occurrence, R¹, R², R³, and R⁴ are independently chosen from H. F, Cl, and Br. At each occurrence R¹, R², R³, and R⁴ can also each be independently chosen from H and F. In some embodiments, the polymer is unbranched. An unbranched polymer is substantially linear. An unbranched polymer, in some embodiments, is not crosslinked. In some embodiments, an uribranched polymer includes R¹, R³ and R⁴ substituents with less than 2, 3, 4, or 5 carbon atoms.

In some embodiments, the polymer can be a co-polymer of at least one monomer selected from trifluoroethylene (TrFE), tetrafluoroethylene (TFE), fluoroethylene (FE), ethylene (ET), 1-chloro-1-fluoroethylene (CFE), chlorotrifluoroethylene (CTFE), chlorodifluoroethylene (CDFE), vinylidene chloride (VDC), tetrachloroethylene (TCE), tetrabromoethylene (TBE), tribromoethylene (TrBE), 1,1-dibromoethylene (DBE), bromoethylene (BE), 1,1-dibrorno-2,2-difluoroethylene (DBDFE), or 1,1-dichloro-2,2-dibromoethylene (DCDBE), or combinations thereof. Thus, the polymer of Formula I can be a co-polymer of vinylidene, fluoride (VF) and any combination of the aforementioned mononers. In some embodiments, the polymer of Formula I is a co-polymer of vinylidene fluoride and any one of the aforementioned monomers. In some embodiments, the polymer is a co-polymer of VP and TrFE.

In a polymer of Formula I that is formed from VF and a monomer as described herein, the amount of VF in the co-polymer can be 1, 2, 3, 4, 5, 6, 7, 8, 9, 10, 15, 20, 25, 30, 35, 40, 45, 50, 55, 60, 65, 70, 75, 80, 85, 90, 95, 96, 97, 98, or 99 mol %, or any range or sub-range between these values. The amount of monomer in the co-polymer of Formula I can be 1, 2, 3, 4, 5, 6, 7, 8, 9, 10, 15, 20, 25, 30, 35, 40, 45, 50, 55, 60, 65, 70, 75, 80, 85, 90, 95, 96, 97, 98, or 99 mol %, or any range or sub-range, between these values.

In some embodiments, the co-polymer comprises a terpolymer. A termpolymer of Formula I contains VF and a first and second monomer, as described herein. The first and second monomers can be different. The amount of each of VF, the first monomer, and the second monomer can be 1, 2, 3, 4, 5, 6, 7, 8, 9, 10, 15, 20, 25, 30, 35, 40, 45, 50, 55, 60, 65, 70, 75, 80, 85, 90, 95, 96, 97, 98, or 99 mol %, or any range or sub-range between these values.

In some embodiments, the polymer exhibits an adiabatic temperature change between 1 and 20° C. when the polymer is exposed to an electric field. Exposing a polymer of Formula I to an electric field can result in an adiabatic temperature change of 1° C., 2° C., 3° C., 4° C., 5° C., 6° C., 7° C., 8° C., 9° C., 10° C., 10.5° C., 11° C., 11.5° C., 12° C., 12.5° C., 13° C., 13.5° C., 14° C., 14.5° C., 15° C., 15.5° C., 16° C., 16.5° C., 17° C., 17.5° C., 18° C., 18.5° C., 19° C., 19.5° C., or 20° C., or any range or sub-range between these values.

In some embodiments, the polymer can have a number average. molecular weight (M_{w}) of between about 5,000 g/mol and about 100,000 g/mol. The polymer can have a number average molecular weight of about 5,000 g/mol to about 95,000 g/mol, 10,000 g/mol to about 90,000 g/mol, 15,000 g/mol to about 85,000 g/mol, 20,000 g/moi to about 80,000 g/mol, 25,000 g/mol to about 70,000 g/mol, 30,000 g/mol to about 65,000 g/mol, or 35,000 g/mol to about 60,000 g/mol. The polymer can have a number average molecular weight of 5,000 g/mol, 7,500 g/mol, 10,000 g/mol, 15,000 g/mol, 20,000 g/mol, 25,000 g/mol, 30,000 g/mol, 35,000 g/mol, 40,000 g/mol, 45,000 g/mol, 50,000 g/mol, 55,000 g/mol, 60,000 g/mol, 65,000 g/mol, 70,000 g/mol, 75,000 g/mol, 80,000 g/mol, 85,000 g/mol, 90,000 g/mol, 95,000 g/mol, or 100,000 g/mol, or any range or sub-range between these values.

### Preparation of Polymers

In some embodiments, a method of making the polymer includes reacting a saturated precursor of the compound of Formula I with a base to form the polymer of Formula I. Scheme 1 illustrates one embodiment of the method.

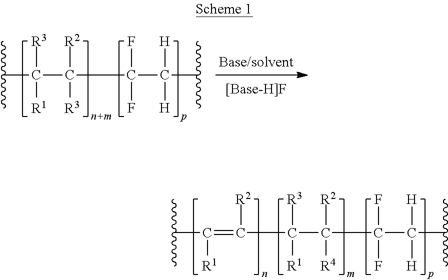

In Scheme 1, a base abstracts a hydrogen from a polymer precursor at R³ or R⁴ with the concomitant elimination of a halogen leaving group at R³ or R⁴. For example, in Scheme 1, R³ can be hydrogen, and R⁴ can be F, Cl, Br, or I. Similarly, in Scheme 1, R⁴ can be hydrogen, and R³ can be F, Cl, Br, or I.

In some embodiments, the base is an alkali metal hydroxide. The alkali metal hydroxide can be LiOH, NaOH, KOH or CsOH. In some embodiments, the base is NaOH, LiOH, KOH, or CsOH.

In some embodiments, the reacting occurs in one or more organic solvents. In some embodiments, the solvent comprises isopropanol and dimethylacetamide. Other suitable solvents include methanol, ethanol, dimethylformamide, tetrahydrofuran, and mixtures thereof. In some embodiments, the solvent has a dimethylacetamide:isopropanol v/v ratio ranging from about 5:1 to about 15:1. The dimethylacetamide:isopropanol v/v ratio can be 6:1, 7:1, 8:1, 9:1, 10:1, 11:1, 12:1, 13:1, 14:1, or 15:1, or any range or sub-range between these values. In some embodiments, the reacting is dehalogenation reaction, and can include dehydrofluroination, dehydrochlorination, dehydrobromination, and dehydroiodination. In sonic embodiments, the reacting is dehydrofluorination.

In some embodiments, a method of making a polymer of Formula I includes dehydrofluorinating polyvinylidene difluoride with NaOH in a solvent comprising a 5:1 to a 10:1 v/v ratio of dimethylacetamide:isopropartol to form the polymer of Formula I, and purifying the polymer of Formula I.

In some embodiments, an electrocaloric relaxor ferroelectric material includes the polymer of Formula I. In some emdboiments, an apparatus for heating or cooling comprising the polymer of Formula I. The apparatus can include a refrigerator, air conditioner, gas liquefier, dehumidifier, heat pump, heat management device, or combinations thereof.

### EXAMPLES

Various embodiments of the present invention can be better understood by reference to the following Examples which are offered by way of illustration. The present invention is not limited to the Examples given herein.

### Example 1

The dehydrofluorination of PVDF (polyvinylidene fluoride) was carried out by dissolving 5 g of PVDF in a 100 ml beaker, containing 75 ml of dimethylacetamide (DMAc). A saturated solution of NaOH in 10 ml of isopropanol was slowly added to the beaker at room temperature. After stirring for at least 30 minutes, dehydrofluorinated PVDF was precipitated using water, filtered, rinsed 3-4 times with water, then dried under vacuum at 55-65° C. The reaction is illustrated in Scheme 2.

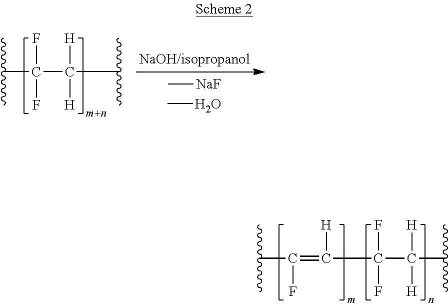

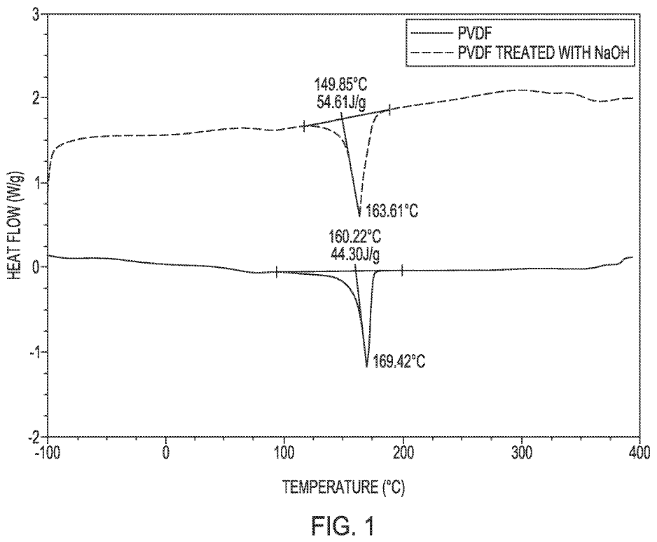

The obtained material was characterized using ATR-FTIR spectroscopy and Differential Scanning calorimetry (DSC). As expected, the FM-spectrum of the starting PVDF polymer did not contain any bands between 1600 and 1700 cm-1, which are typically present in the spectra of unsaturated organic molecules containing C═C— double bonds in their structure. However, the material formed after the NaOH treatment clearly showed such band in its spectrum, which confirmed HF extraction and indicated the formation of —C═C— double bonds. The DSC data illustrated in FIG. 1 agreed with the FTIR results. The NaOH treated PVDF showed clear melting point depression by ˜6° C. compared to starting PVDF, which further confirmed the chemical transformation of PVDF into a polymer of Formula I.

The terms and expressions that have been employed are used as terms of description and not of limitation, and there is no intention in the use of such terms and expressions of excluding any equivalents of the features shown and described or portions thereof, but it is recognized that various modifications are possible within the scope of the embodiments of the present invention. Thus, it should be understood that although the present invention has been specifically disclosed by specific embodiments and optional features, modification and variation of the concepts herein disclosed may be resorted to by those of ordinary skill in the art, and that such modifications and variations are considered to be within the scope of embodiments of the present invention.

### Enumerated Embodiments

The following exemplary embodiments are provided, the numbering of which is not to be construed as designating levels of importance:

Embodiment 1 provides a polymer having the formula:

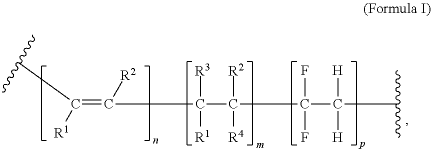

wherein n is an integer ranging from 1 to 1000, m is an integer ranging from 1 to 1000, p is an integer greater than n+m, wherein at each occurrence R¹, R², R³, and R⁴ are independently chosen from H, F, Cl, Br, I, —NH₂, —NHZ, —NZ₂, —BH₂, —BHZ, —BZ₂, OZ, —SeZ, —TeZ, —SO₂Z, —OCOZ, —NHCOZ, —COOZ, —CONH₂, —CONHZ, —CONZ₂, —CH₂F, and —CHF₂, wherein Z is independently at each occurrence hydrogen, alkyl, aryl, or aralkyl.

Embodiment 2 provides the polymer of embodiment 1, wherein at each occurrence R¹, R², R³, and R⁴ are independently chosen from H, F, Cl, and Br.

Embodiment 3 provides thepolymer of any one of embodiments 1-2, wherein at each occurrence R¹, R², R³, and R⁴ are each independently chosen from H and F.

Embodiment 4 provides the polymer of any one of embodiments 1-3, wherein the polymer is unbranched.

Embodiment 5 provides the polymer of any one of embodiments 1-4, wherein the polymer comprises a co-polymer of at least one monomer selected from trifluoroethylene (TrFE), tetralluoroethylene (TFE), fluoroethylene (FE), ethylene (ET), 1-chloro-1-fluoroethylene (CFE), chlorotrifluoroethylene (CTFE), chlorodifluoroethylene (CDFE), vinylidene chloride (VDC), tetrachloroethylene (TCE), tetrabromoethylene (TBE), tribromoethylene (TrBE), 1,1-dibromoethylene (DBE), bromoethylene (BE), 1,1-dibromo-2,2-difluoroethylene, (DBDFE), or 1,1-dichloro-2,2-dibromoethylene (DCDBE), or combinations thereof.

Embodiment 6 provides the polymer of any one of embodiments 1-5, wherein the co-polymer comprises a terpolymer.

Embodiment 7 provides the polymer of any one of embodiments 1-6, wherein the polymer exhibits an adiabatic temperature change of at least 1° C. when the polymer is exposed to an electric field.

Embodiment 8 provides the polymer of any one of embodiments 1-7, wherein the polymer has a number average molecular (M_{w}) weight of between about 5,000 g/mol and about 100,000 g/mol.

Embodiment 9 provides the polymer of any one of embodiments 1-8, wherein the polymer is a co-polymer of TrFE.

Embodiment 10 provides a method of making the polymer of any one of embodiments 1-9, comprising: reacting a saturated precursor of the compound of Formula I with a base to form the polymer of Formula 1.

Embodiment 11 provides the method of any one of embodiments 10, wherein the base is an alkali metal hydroxide.

Embodiment 12 provides the method of any one of embodiments 10-11, wherein the alkali metal hydroxide is NaOH.

Embodiment 13 provides the method of any one of embodiments 10-12, wherein the reacting occurs in one or more organic solvents.

Embodiment 14 provides the method of any one of embodiments 10-13, wherein the solvent comprises isopropanol and dimethylacetamide.

Embodiment 15 provides the method of any one of embodiments 10-14, wherein the solvent has a dimethylacetamide:isopropanol v/v ratio ranging from about 5:1 to about 15:1.

Embodiment 16 provides the method of any one of embodiments 10-15, wherein the reacting comprises dehydrofluorination.

Embodiment 17 provides a method of making a polymer of any one of embodiments 1-9, comprising: dehydrofluorinating polyvinylidene difluoride with NaOH in a solvent comprising a 5:1 to a 10:1 v/v ratio of dimethylacetamide:isopropanol to form the polymer of Formula I; and purifying the polymer of Formula I.

Embodiment 18 provides an electrocaloric relaxor ferroelectric material comprising the polymer of any one of embodiments 1-9.

Embodiment 19 provides an apparatus for heating or cooling comprising the polymer of any one of embodiments 1-9.

Embodiment 20 provides the apparatus of embodiment 19, erein the apparatus comprises a refrigerator, air conditioner, gas liquefier, dehumidifier, heat pump, heat management device, or combinations thereof.

What is claimed is:

1. A method of heating or cooling, the method comprising:
transferring heat between a material and a polymer comprising the following formula: 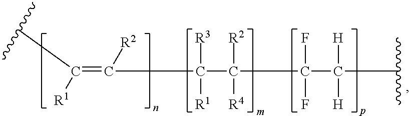
wherein
n is an integer ranging from 1 to 1000,
m is an integer ranging from 1 to 1000,
p is an integer greater than n+m,
at each occurrence R¹, R², R³, and R⁴ are independently chosen from H, F, Cl, Br, I, —NH₂, —NHZ, —NZ₂, —BH₂, —BHZ, —BZ₂, OZ, —SeZ, —TeZ, —SO₂Z, —OCOZ, —NHCOZ, —COOZ, —CONH₂, —CONHZ, —CONZ₂, —CH₂F, and —CHF₂, and
Z is independently at each occurrence hydrogen, alkyl, aryl, or aralkyl;
exposing the polymer to an electric field such that that polymer undergoes a temperature change; and
repeating the transferring and exposing steps such that the material is heated or cooled by the polymer.

2. The method of claim 1, wherein the method is performed by an apparatus comprising a refrigerator, air conditioner, gas liquefier, dehumidifier, heat pump, heat management device, or a combination thereof.

3. The method of claim 1, wherein at each occurrence R¹, R², R³, and R⁴ are independently chosen from H, F, Cl, and Br.

4. The method of claim 1, wherein at each occurrence R¹, R², R³, and R⁴ are each independently chosen from H and F.

5. The method of claim 1, wherein the polymer is unbranched.

6. The method of claim 1, wherein at least one of R¹, R², R³, and R⁴ is Br, I, NH₂, —NH, —NHZ, —NZ₂, —BH₂, —BHZ, —BZ₂, OZ, —SeZ, —TeZ, —SO₂Z, —OCOZ, —NHCOZ, —COOZ, —CONH₂, —CONHZ, —CONZ₂, —CH₂F, or —CHF₂; or wherein —C(R³)(R¹)—C(R²)(R⁴)— is a monomer selected from tetrafluoroethylene (TFE), ethylene (ET), 1-chloro-1-fluoroethylene (CFE), chlorodifluoroethylene (CDFE), tetrachloroethylene (TCE), tetrabromoethylene (TBE), tribromoethylene (TrBE), 1,1-dibromoethylene (DBE), bromoethylene, (BE), 1,1-dibromo-2,2-difluoroethylene (DBDFE), and 1,1-dichloro-2,2-dibromoethylene (DCDBE).

7. The method of claim 1, wherein —C(R³)(R¹)—C(R²)(R⁴)— is selected from trilluoroethylene (TrFE), tetrafluoroethylene (TFE), fluoroethylene (FE), ethylene (ET), 1-chloro-1-fluoroethylene (CFE), chlorotrifluoroethlene (CTFE), chlorodifluoroethylene (CDFE), vinylidene chloride (VDC), tetrachloroethylene (TCE), tetrabromoethylene (TBE), tribromoethylene (TrBE), 1,1-dibromoethylene (DBE), bromoethylene (BE), 1,1-dibromo-2,2-difluoroethylene (DBDFE), and 1,1-dichloro-2,2-dibromoethylene (DCDBE).

8. The method of claim 1, wherein —C(R³)(R¹)—C(R²)(R⁴)— is selected from tetrafluoroethylene (TFE), ethylene (ET), 1-chloro-1-fluoroethylene (CFE), chlorodifluoroethylene (CDFE), tetrachloroethylene (TCE), tetrabromoethylene (TBE), tribromoethylene (TrBE), 1,1-dibromoethylene (DBE), bromoethylene (BE), 1,1-dibromo-2,2-difluoroethylene (DBDFE), and 1,1-dichloro-2,2-dibromoethylene (DCDBE).

9. The method of claim 1, wherein the polymer is a terpolymer.

10. The method of claim 1, wherein the polymer further comprises at least one monomer selected from trifluoroethylene (TrPE), tetrafluoroethylene (TFE), fluoroethylene (FE), ethylene (ET), 1-chloro-1-fluoroethylene (CFE), chlorotrifluoroethylene (CTFE), chlorodifluoroeth:,lene (CDFE), vinylidene chloride (VDC), tetrachloroethylene (TCE), tetrabromoethylene (TBE), tribromoethylene (TrBE), 1,1-dibromoethylene (DBE), bromoethylene (BE), 1,1-dibromo-2,2-difluoroethylene (DBDFE), and 1,1-dichloro-2,2-dibromoethylene (DCDBE).

11. The method of claim 1, wherein the polymer exhibits an adiabatic temperature change of at least 1° C. when the polymer is exposed to an electric field.

12. The method of claim 1, wherein the polymer has a number average molecular (M_{w}) weight of between about 5,000 g/mol and about 100,000 g/mol.

13. The method of claim 1, wherein the polymer is a co-polymer of TrFE.

14. The method of claim 1, wherein an electrocaloric relaxor ferroelectric material comprises the polymer, wherein the transferring of heat between the material and the polymer comprises transferring heat between the material and the electrocaloric relaxor ferroelectric material.

15. The method of claim 1, wherein the transferring of the heat between the material and the polymer comprises transferring heat from the material to the polymer, wherein the exposing of the polymer to the electric field is performed such that a temperature of the polymer becomes cooler.

16. The method of claim 1, wherein the transferring of the heat between the material and the polymer comprises transferring heat from the polymer to the material, wherein the exposing of the polymer to the electric field is performed such that a temperature of the polymer becomes warmer.

17. A method of heating or cooling, the method comprising:
transferring heat between a material and a polymer comprising the following formula: 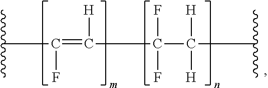
wherein n is an integer ranging from 1 to 1000 and m is an integer ranging from 1 to 1000;
exposing the polymer to an electric field such that that polymer undergoes a temperature change; and
repeating the transferring and exposing steps such that the material is heated or cooled by the polymer.

18. The method of claim 17, wherein the method is performed by an apparatus comprising a refrigerator, air conditioner, gas liquefier, dehumidifier, heat pump, heat management device, or a combination thereof.

19. The method of claim 17, wherein the polymer has a number average molecular (M_{w}) weight of between about 5,000 g/mol and about 100,000 g/mol.
